(19) United States
(12) Patent Application Publication
(10) Pub. No.: US 2025/0379026 A1
(43) Pub. Date: Dec. 11, 2025

(54) COMPACT BEAM PROCESSING SYSTEM HAVING IN-SITU IMAGING METROLOGY

(71) Applicant: Applied Materials, Inc., Santa Clara, CA (US)

(72) Inventors: Ryan PRAGER, Beverly, MA (US); Alexander S. PEREL, Danvers, MA (US)

(73) Assignee: Applied Materials, Inc., Santa Clara, CA (US)

(21) Appl. No.: 18/927,064

(22) Filed: Oct. 25, 2024

Related U.S. Application Data
(60) Provisional application No. 63/656,919, filed on Jun. 6, 2024.

(51) Int. Cl. H01J 37/30; H01J 37/244; H01J 37/32

(52) U.S. Cl. CPC H01J 37/3007; H01J 37/244; H01J 37/3299; H01J 2237/24528; H01J 2237/30472

(57) ABSTRACT

A processing system. The processing system may include a plasma chamber to generate a plasma; an extraction system, to extract an ion beam from the plasma chamber and deliver the ion beam to a substrate position, external to the plasma chamber; and an in-situ beam metrology system, having at least one detector to image the ion beam in imaging region that extends between the plasma chamber and the substrate position.

### RELATED APPLICATIONS

The application claims priority to U.S. Provisional patent application Ser. No. 63/656,919, filed Jun. 6, 2024, entitled COMPACT ION BEAM PROCESSING SYSTEM HAVING IN-SITU IMAGING METROLOGY, and incorporated by reference herein in its entirety.

### FIELD OF THE DISCLOSURE

The disclosure relates generally to processing apparatus, and more particularly to plasma based compact ion beam apparatus.

### BACKGROUND OF THE DISCLOSURE

In the present day, plasmas are used to process substrates, such as electronic devices, for applications such as substrate etching, layer deposition, ion implantation, and other processes. Some processing apparatus employ a plasma chamber that generates a plasma to act as an ion source for substrate processing. A beam such as an ion beam may be extracted through an extraction assembly and directed to a substrate in an adjacent chamber. This plasma may be generated in various ways.

In various commercial systems, plasma chambers employ ion beam extraction optics to generate an extracted ion beam. In some examples, an extraction aperture may be provided along a side or edge of a plasma chamber to extract an ion beam. The extraction aperture may generate an ion beam having a determined shape, size, and angle of incidence with respect to a substrate plane of a substrate to be processed by the ion beam. During processing, changes in ion beam characteristics, such as changes in angle of incidence, beam shape, and beam size, may result in a variation of processing results within and between substrates to be processed.

With respect to these and other considerations the present disclosure is provided.

### BRIEF SUMMARY

In one embodiment, a processing system is provided. The processing system may include a plasma chamber to generate a plasma; an extraction system, to extract a beam from the plasma chamber and deliver the beam to a substrate position, external to the plasma chamber; and an in-situ beam metrology system, having at least one detector to image the beam in an imaging region that extends between the plasma chamber and the substrate position.

In another embodiment, an in-situ metrology system to measure a beam is provided. The in-situ metrology system may include a detector, arranged to intercept radiation from the beam over an imaging region that extends between a plasma chamber and a substrate position, wherein the detector comprises a two-dimensional detector to generate a two-dimensional image of the beam.

In another embodiment, a method of substrate processing is provided, including: directing an ion beam from a plasma chamber to a substrate; and measuring a beam characteristic of the ion beam using a metrology system that include a 2-dimensional imaging component.

### BRIEF DESCRIPTION OF THE DRAWINGS

FIG. 1A shows a side view of an exemplary processing system, according to embodiments of the disclosure;

FIG. 1B shows an end view of the processing system of FIG. 1A;

FIG. 1C shows a top view of the processing system of FIG. 1A;

FIG. 1D shows details of an exemplary controller;

FIG. 2A shows a side view of a plasma chamber arrangement, according to embodiments of the disclosure;

FIG. 2B shows a side view of another plasma chamber arrangement, according to embodiments of the disclosure;

FIG. 2C shows a side view of a further plasma chamber arrangement, according to embodiments of the disclosure;

FIG. 2D shows a side view of still another plasma chamber arrangement, according to embodiments of the disclosure;

FIG. 3A shows a front view of the geometry of an in-situ metrology system, according to some embodiments;

FIG. 3B shows a side view of the geometry of the in-situ metrology system of FIG. 3A, according to some embodiments;

FIG. 4 is a composite illustration depicting one embodiment of ion beam imaging;

FIG. 5A is a side cross-sectional view of an exemplary optics and imaging metrology arrangement, according to embodiments of the disclosure; and

FIG. 5B is a top view of the arrangement of FIG. 5A;

FIG. 6A depicts an ion beam imaging system, according to embodiments of the disclosure;

FIG. 6B depicts another ion beam imaging system, according to embodiments of the disclosure;

FIG. 7A depicts an exemplary process flow;

FIG. 7B depicts a further exemplary process flow;

FIG. 8A another exemplary process flow;

FIG. 8B depicts another exemplary process flow;

FIG. 9 depicts another exemplary process flow; and

FIG. 10 depicts another exemplary process flow.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not to be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for measuring beams in an in-situ manner, such as in compact ion beam systems. In various embodiments, a system may be a plasma based system, where a plasma chamber acts as an ion source. Such systems include a capacitively coupled plasma system, inductively coupled plasma system, a DC based plasma system, such as an indirectly heated cathode system, a pulse laser system, a glow discharge system, a processing system employing Kaufmann ion source, a source for a gas cluster ion beam (GCIB) system, and so forth. In particular embodiments, a compact beam system may employ an extraction bias plate (or ion beam optics on an implanter) where a wafer/platen can be mounted, such that ions are extracted from an ion source and directed to a substrate with an energy proportional to the bias voltage between ion source and substrate. In an alternative embodiment, the ion beam may be composed of radicals that are desirable for surface reactions with a wafer, and a bias plate need not be present. In further embodiments a beam may be provided form a gas cluster ion beam source that delivers clusters to a substrate with a relatively lower energy per atom, such as several eV per atom up to 20 eV per atom. According to various embodiments of the disclosure, a substrate may be scanned up and down, and/or side-to side through an ion beam, where the beam may have relatively narrow dimension in at least one direction with respect to the substrate size.

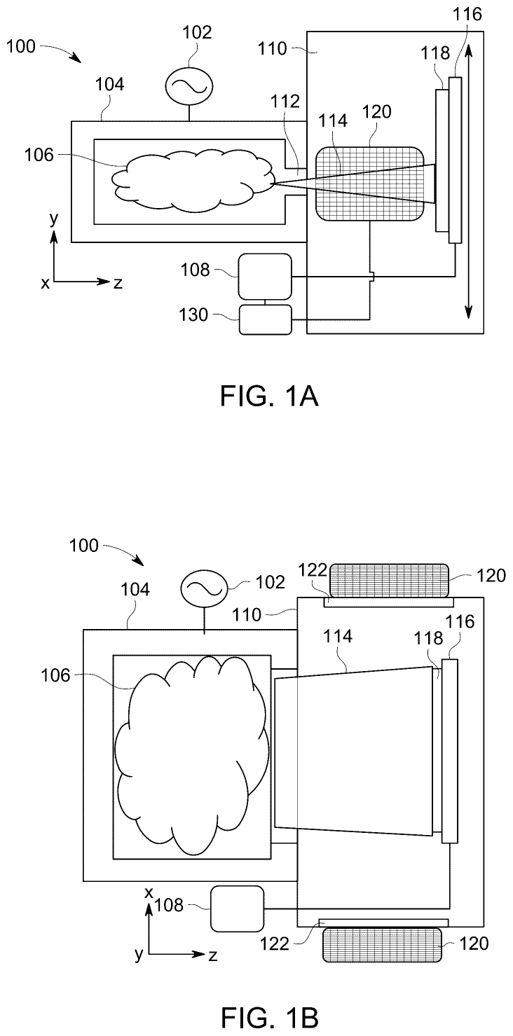

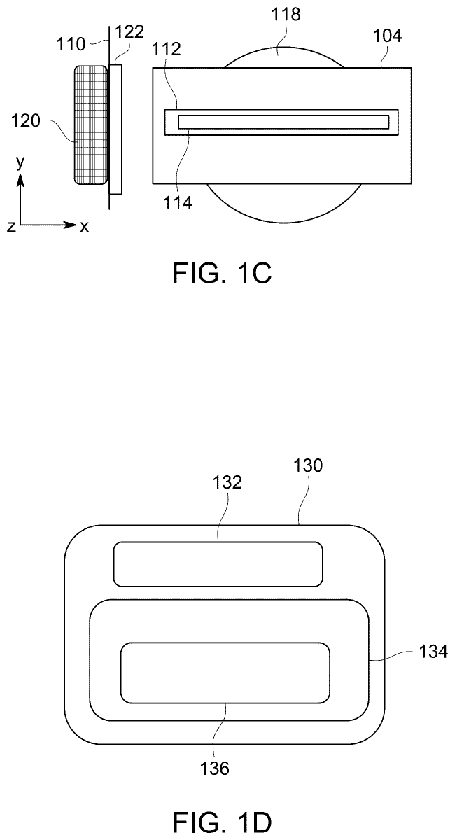

FIG. 1A shows a side view of an exemplary system, according to embodiments of the disclosure. FIG. 1B shows an end view of the processing system of FIG. 1A; according to embodiments of the disclosure, while FIG. 1C shows a top view of the processing system of FIG. 1A. The system will be referred to herein as processing system 100. The processing system 100 may be suitable for ion beam processing of a substrate 118. The processing system 100 includes a plasma chamber 104 to house a plasma 106, a power generator 102, coupled to deliver power to generate the plasma 106, when a suitable gaseous species (not separately shown) is delivered to the plasma chamber 104. The power generator 102 may be an RF power generator, for example, arranged to generate an inductively coupled plasma according to some non-limiting embodiments. However, in other embodiments, the plasma 106 may be generated by any suitable means. A beam extraction supply 108 is provided, connected to the plasma chamber 104 to generate an extraction potential between the plasma chamber 104 and a substrate holder 116, in a process chamber 110 (typically at earth ground). This arrangement supplies the potential that defines the energy of ions of an ion beam 114 striking the substrate 118. As shown, the plasma chamber 104 may be provided with an extraction aperture 112, through which aperture ions are extracted to form the ion beam 114.

As shown in FIG. 1A, a substrate 118 may be disposed in a process chamber 110, adjacent the plasma chamber 104, on a substrate holder 116. The substrate 118 and substrate holder 116 may be oriented such that the wafer normal is parallel to the axis of the extracted ion beam (meaning parallel to the Z-axis of the Cartesian coordinate system shown), as shown, or is tilted at some angle to this axis. The substrate 118 and substrate holder 116 may also be also may be rotated about the Z-axis or moved along the Y-axis, in the ion beam 114 to expose different portions of the substrate 118 to the ion beam 114.

As depicted in FIG. 1A, the ion beam 114 may be characterized by a shape, a size, and angle, an angular spread, as well as a position, with respect to a substrate 118. For example, in the ‘side view’ of FIG. 1A, the ion beam 114 may exhibit a somewhat triangular shape where the ion beam expands in height along the y-direction from a relatively smaller height at the extraction aperture 112 to a relatively greater height at the substrate 118. According to embodiments of the disclosure, the processing system 100 is provided with a metrology system to perform in-situ metrology of the ion beam 114. In particular, a detector 120 is provided that is arranged to intercept radiation from the ion beam 114 over an imaging region that extends between the plasma chamber 104 and a substrate position, as represented by the substrate 118, for example, when mounted on the substrate holder 116. In particular, the detector 120 may be a two-dimensional imaging detector arranged to generate a two-dimensional image of the ion beam 114. In the arrangement of FIG. 1A to FIG. 1C, the detector 120 may be arranged in a manner to record an image of the ion beam essentially along an imaging plane that extends parallel to the Y-Z plane, as defined in the figures. The imaging geometry of detectors of the present embodiments is further detailed with respect to embodiments to follow.

In various embodiments, the detector 120 may be arranged on or adjacent to the process chamber 110, as shown in FIG. 1B. For example, the detector 120 may be arranged external to the process chamber 110, on a side of the process chamber 110. An optical window 122 may be arranged in a wall of the process chamber 110 to permit radiation to pass from ion beam 114 to detector 120. In some examples, a detector 120 may be arranged on two sides of the process chamber 110, as shown. As detailed below, during processing of the substrate, the ion beam 114 may be imaged by the detector 120, such as recording a real-time image, storing an image, storing a series of images, and so forth. The processing system 100 may further include a controller 130, with the operation of the controller 130 detailed below, with respect to FIG. 1D.

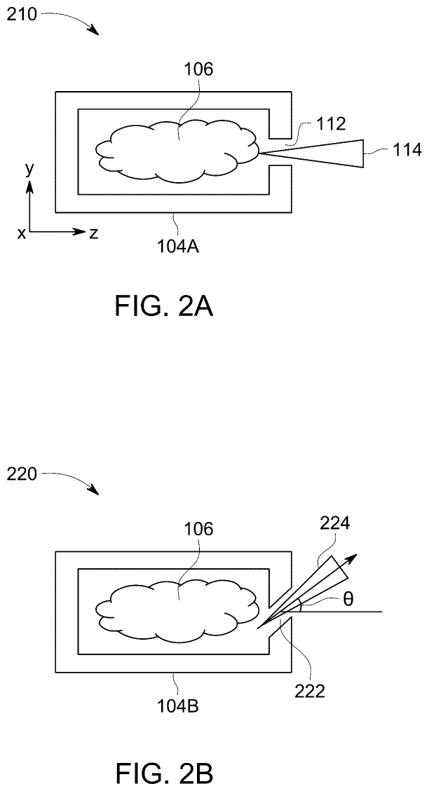

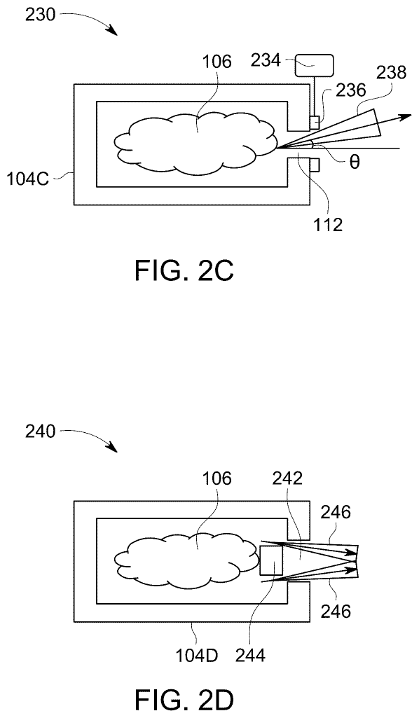

According to various embodiments of the disclosure, an in-situ metrology system may be used to monitor ion beams having a variety of configurations. To emphasize this point FIG. 2A shows a side view of a plasma chamber arrangement, according to embodiments of the disclosure. FIG. 2B shows a side view of another plasma chamber arrangement, according to embodiments of the disclosure while FIG. 2C shows a side view of a further plasma chamber arrangement, according to embodiments of the disclosure, and FIG. 2D shows a side view of still another plasma chamber arrangement, according to embodiments of the disclosure.

In the arrangement 210, a plasma chamber 104A includes a single aperture, shown as extraction aperture 112, generating an unguided beam, shown as ion beam 114. The ion beam 114 may extend along a direction, where the central trajectory of the ion beam 114 lies along the Z-axis, while the ion beam 114 also has an angular spread as shown. In the arrangement 220 of FIG. 2B, a plasma chamber 104B includes an angled aperture 222 that provides a mechanically guided angled ion beam, shown as ion beam 224, where the mean trajectory of ions define a non-zero angle, θ, with respect to the substrate normal, meaning the Z-axis. In the arrangement 230 of FIG. 2C, a plasma chamber 104C includes an electrostatic electrode assembly 236, providing tuning electrodes that are arranged on the internal or external side of the plasma chamber 104C, or a combination of the two to provide an electrostatically guided angled ion beam. Note that by applying a suitable bias from a power supply 234 to the electrostatic electrode assembly 236, the value of the non-zero angle, θ, may be adjusted. In the arrangement 240 of FIG. 2D, a plasma chamber 104D may be arranged with a beam blocker 244 that is adjacent to an extraction aperture 242 to define a pair of beamlets, shown as beamlets 246, which beamlets may by angled at a non-zero angle with respect to the substrate normal (z-axis). In certain embodiments of the present disclosure, any of the arrangements of FIGS. 2A-2D may be modified to include several independent electrodes, where each electrode may be biased by common, or independent power supplies in order to obtain unique ion beam shapes. In additional configurations, a beam blocker may be combined with the arrangements of FIGS. 2A-2C to define further variants of ion beam geometries.

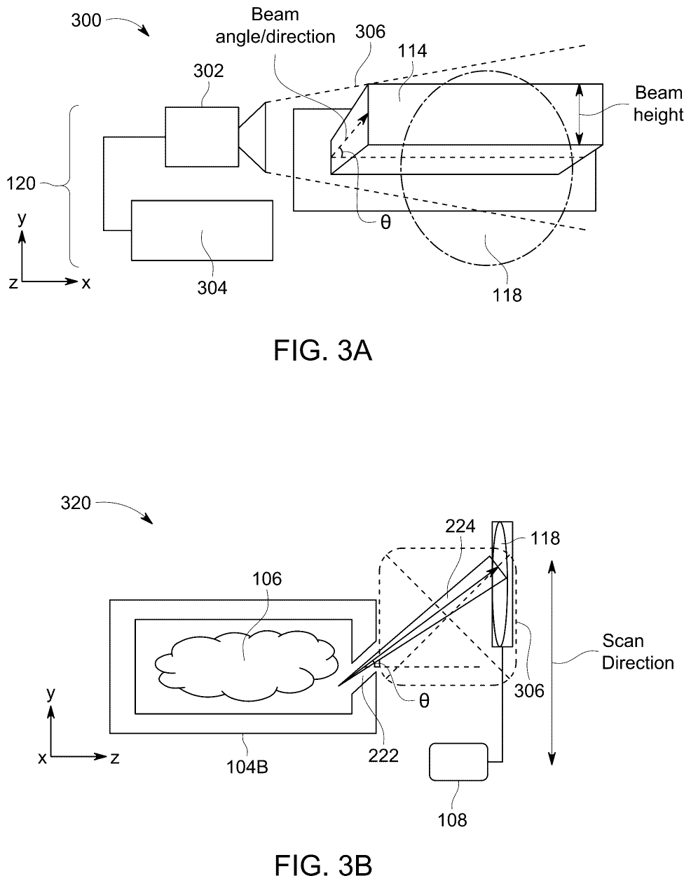

To further explain operation of the present embodiments, FIG. 3A shows a front view of the geometry of an in-situ metrology system, according to some embodiments. FIG. 3B shows a side view of the geometry of the in-situ metrology system of FIG. 3A, according to some embodiments. The metrology system 300 includes an image detector 302 that is physically arranged to receive radiation, generally in the form of visible light, near infrared radiation, and near ultraviolet radiation, or a combination of the above. The image detector 302 may be arranged to receive light over a field of vision 306, as shown by the dotted line. In FIG. 3A, the substrate 118 (such as a semiconductor wafer) is arranged in X-Y plane, while an ion beam 114 is directed to the substrate along a given general direction, where the given direction may lie along the Z-axis, may define a non-zero angle with respect to the Z-axis, and may define an angular spread. Note that particular species associated with the ion beam 114 will emit radiation that is received by the image detector 302, and may be used to form an image of the ion beam 114. In particular, the image of the ion beam 114 may represent a cross-section of the ion beam 114 that is generally formed within the Y-Z plane.

As noted previously, the image detector, such as image detector 302, may be mounted on the side of a process chamber that houses the substrate 118. The image detector 302 may be coupled to an electronic processor, such as a computer 304, arranged for image and data processing. The image detector mounting direction is thus parallel to an axis along the length of the ion beam extraction optics centerline, parallel to the Y-Z plane of the ion beam 114, but perpendicular to the extraction direction of the ion beam 114.

In various embodiments, the image detector 302 mounting location may be mounted to the wall of a vacuum chamber on the atmospheric side, facing through a lens/window. The window may be made of a transparent, crystalline or amorphous material to enable image capture by image detector 302. Common materials of such windows include, but are not limited to: plexiglass and other polymers, silicon-oxide (glass/quartz), aluminum oxide (sapphire), MgF₂, CaF₂, KBr, BaF₂, and more, as well as coated or composite variants of the materials above. Different windows may not enable certain optical bands and wavelengths through, enabling filtering. In various embodiments, an optical window may be mounted in a location so as to reduce or minimize accumulation of material on the optical window during substrate processing.

In another embodiment, the image detector 302 may be mounted inside the vacuum chamber (meaning inside a process chamber (not shown), if camera components and cabling are vacuum compatible.

In various embodiments, the image detector 302 may be a charge coupled device (CCD) or CMOS based camera without color filters applied over the pixels. This arrangement means that the light intensity pixels of such a detector will generate a response that is in proportion to the overall light intensity in certain regions of the field of view, which light intensity in turn corresponds to ion density in said regions. As such, the variable response of different pixels in the image detector 302 as a function of position in the plane of the image sensor of the detector will define an overall ion beam shape.

To explain in more detail how the detector may image an ion beam, note that atoms and molecules ionized by plasma interactions will emit photons upon decay from an excited state either to the ground state, or an intermediate energy state (between excited and ground). Atoms and molecules that occupy the space where the ion beam is present and are energized by interactions with ions in an ion beam will emit light around one or several characteristic energies and wavelengths (and/or bands of both), depending on the specific transitions possible for each component, and the energetics of the ion/molecules/electrons in the system. The intensity (I_{λ}) of a wavelength (λ) or band is directly proportional to the density of the species (n_{A}) and the energy transitions occurring for said species (α_{λA}): I_{λ}=n_{A}*α_{λA}

CMOS and CCD image sensor cells are based on a MOS (metal-oxide-semiconductor), or upon a semiconductor capacitor cell structure that stores charge, and can be read out via additional circuitry (integrated CMOS transistors, by shift registers in the case of CCD, or external circuitry). When light that is generated by species excited by interaction with the ions of an ion beam impacts the sensor cells, charge is generated in the capacitor cells via the photoelectric effect. The amount of charge generated in each cell (q), or “pixel”, is proportional to the free carrier generation rate (G), which rate is dependent on the flux of photons incident on the cell surface (ϕₛ) and the absorption coefficient of the cell material for the incoming photons (β). Light absorption of a material varies for different photon wavelengths and energies, and therefore so does free carrier generation from the photoelectric effect. Assuming a uniform absorption throughout the cell, the charge in each cell can be related to the cumulative free carrier generation due to all the photons of various wavelengths (λ) can be described by the following relationship:

$$q ∝ G = {\int }_{{λ}_{1}}^{{λ}_{2}} \{ {β}_{λ} * {ϕ}_{s λ} * exp ( - {β}_{λ} * z ) \} d λ ,$$

where the boundaries of the integral are the boundaries of the light spectrum observable by the pixel cell, and z is the cell depth relative to the surface. The resulting charge held in each pixel can then be read out to a computer for post processing, creating an image where the brightness of each pixel is proportionate to the respective light absorbed. Therefore, the brightness pattern of an array of pixels in a CMOS of CCD detector will serve as an image of the ion beam generating the light. Thus, one may understand that the ions of the ion beam may generate light indirectly by interacting with species such as atoms and molecules, which species directly emit the light.

The relationship between the ion beam shape and a detector is further illustrated in FIG. 3B, depicting a processing system 320. The processing system 320 includes a plasma chamber 104B that has an angled aperture 222 to generate an angled ion beam 224 that is directed to the substrate 118. The angled ion beam 224 may define an angled, triangular shape in the Y-Z plane. Because some of the light generated by the angled ion beam 224 may be directed towards a detector that has a field of vision 306, this light will form a detected image in a two dimensional plane of the detector that lies parallel to the Y-Z plane, such that the detected image may capture the actual shape and position of the angled ion beam 224 as viewed along the X-direction.

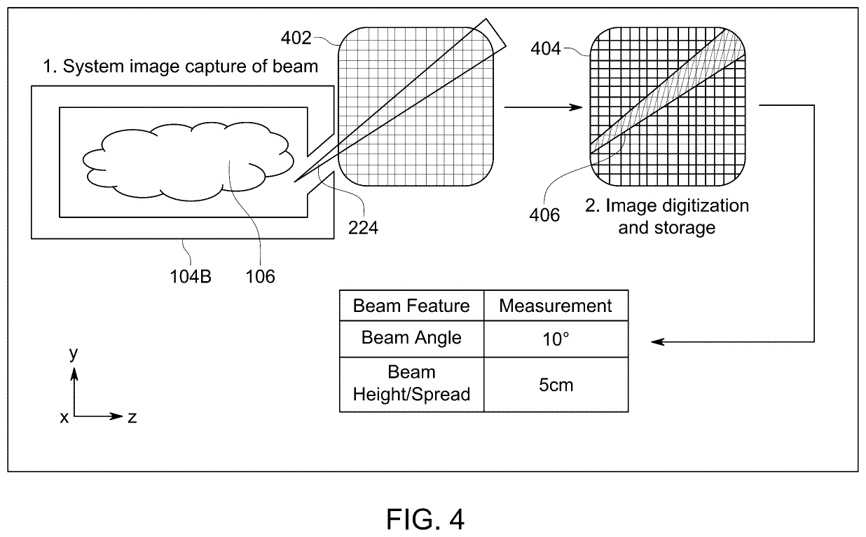

FIG. 4 is a composite illustration depicting one embodiment of ion beam imaging. In this example, a processing system may include the plasma chamber 104B, generating an angled ion beam 224, as shown. The angled ion beam 224 is shown superimposed over a detector 402 that may be positioned as shown in the aforementioned embodiments. In various non-limiting embodiments, the detector 402 may represent a two-dimensional detector such as a CMOS or CCD detector that has a two-dimensional array of pixels, as detailed above. In one non-limiting embodiment, the detector 402 may include a 16×16 pixel array, where brightness or other parameter of each pixel is recorded when exposed to the ion beam 224. As shown in FIG. 4, the brightness pattern of the different pixels may be stored in a suitable memory such as a solid state memory, as a digital pattern 404, corresponding to a two-dimensional array. This brightness pattern may be used to define a beam image 406. In some embodiments, the beam image 406 may be recorded at a given instance in time, may be recorded multiple times, and may be stored as separate images. The beam image 406 or similar digital information generated by the detector 402 may be used by an electronic processor, routine, and so forth, for image processing to generate various values of different features or parameters, such as beam shape, beam height, beam angle, beam spread. Note that a table is included with exemplary values merely for the purposes of illustration.

More generally, because the optical metrology system such as detector 402 is dependent on the flux of light interacting with the cells of the image sensor, and the light emitted from the plasma is dependent on the concentration of excited atoms and molecules, the image sensor may perform the following:
a) Distinguish between the beam and other aspects of the vacuum (process) chamber in order to measure beam shape, height, and angle. For purposes of illustration, FIG. 4 presents one example measurement of beam height (5 cm) and beam angle (10 degrees, which angle may be measured with respect to a fixed direction, such as the Z-direction).
b) Offer qualitative and semi-quantitative information concerning species density within different regions of the ion beam based on intensity/brightness differences between pixels.
c) may be used to calculate beam uniformity (e.g., in an Argon plasma where there is just one constituent element)

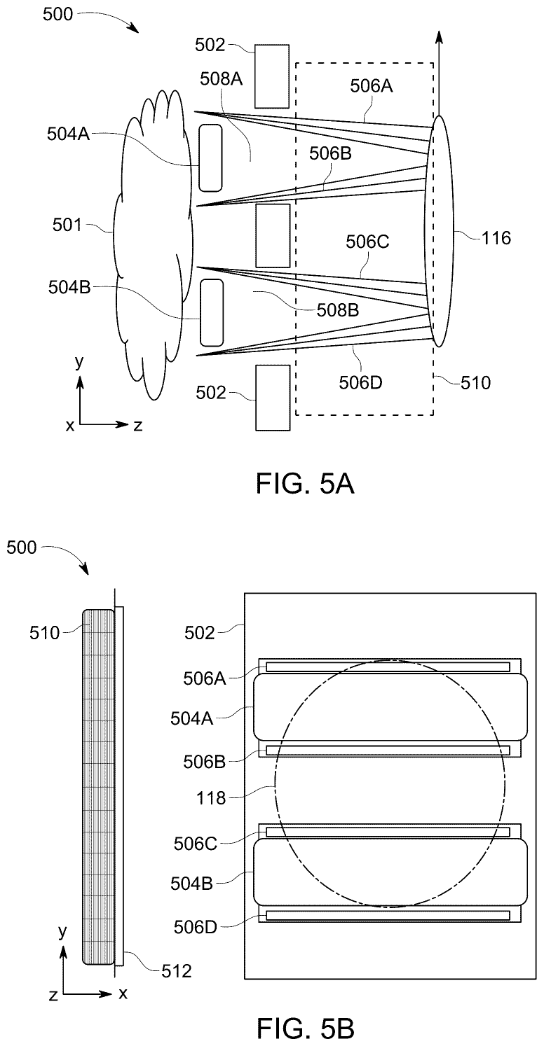

FIG. 5A is a side cross-sectional view of an exemplary optics and imaging metrology arrangement, according to embodiments of the disclosure. FIG. 5B is a top view of the arrangement of FIG. 5A. In FIG. 5A, the arrangement 500 may be understood to represent a portion of a compact ion beam processing system that includes a plasma chamber to generate a plasma 501. An extraction plate 502 is provided along a side of the plasma chamber, having an aperture 508A and aperture 508B. In this example, these apertures constitute elongated extraction apertures that are elongated along an aperture axis that extends in the X-direction, as shown in FIG. 5B, to generate ion beams that are similarly elongated, and may be referred to as ribbon beams. the arrangement 500 further includes a beam blocker 504A and beam blocker 504B, arranged adjacent the aperture 508A and aperture 508B, respectively. As such each combination of beam blocker and aperture define a pair of ion beamlets. These beamlets are shown as beamlet 506A, beamlet 506B, beamlet 506C, and beamlet 506D. In this example, a detector 510 may be arranged to intercept light over a region of interest as shown, extending between the extraction plate 502 and substrate position, represented by substrate 118.

In the case where ion beam extraction optics resulting in multiple ribbon beamlets are used, as in FIG. 5A, the same principles previously outlined may be used to monitor the shape and angles of each beamlet individually. Note that in this embodiment, a detector and/or lens/window 512 with a sufficient field of view will be required, and more computing power required to perform image processing of the larger and more complex images.

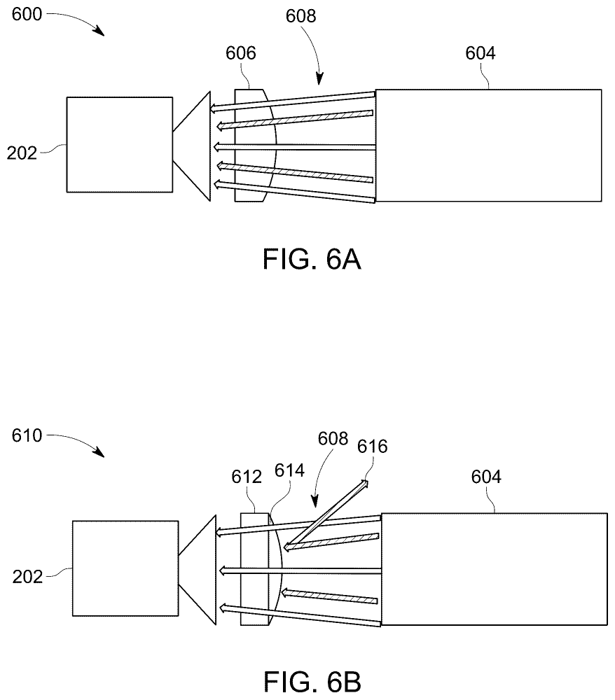

FIG. 6A depicts an ion beam imaging system, according to embodiments of the disclosure, while FIG. 6B depicts another ion beam imaging system, according to embodiments of the disclosure. The beam imaging system 600 may include a detector 202, as described above, as well as a window 606, arranged to transmit radiation from an ion beam 604 to the detector 202. The window 606 may be formed of known material. Image sensor capability in the detector 202 may range from low-density to high-density sensors. The operation capability of such a detector 202 may range from a regular speed (single digit frames per second—ideally 2+) to a relatively higher speed, (up to MHz refresh rate, or 10⁶ frames per second).

The beam imaging system 610 of FIG. 6B may include a detector 202, as described above, as well as a window 612, arranged to transmit radiation from an ion beam 604 to the detector 202. The window 612 may include a known base window material as well as a filter layer 614. The filter layer may filter out specific wavelengths 616 of radiation 608, as shown. As mentioned previously, different window or lens materials/coatings allow just certain individual light wavelengths, or ranges of light wavelengths, to transmit through. This filtering may help add image clarity formed by detector 202 by restricting the wavelengths that can interact with the image detector. Benefits of this embodiment include: 1) Restricting pixel exposure to wavelengths of light originating from the ion beam 604, while reducing the capture of ambient or surrounding light, which surrounding light may decrease the sharpness of the captured beam image. This restricting can increase the accuracy of calculated values of various ion beam parameters. In one example, instead of using a standard window/lens made of silica (transmittance in wavelength range from 200 nm-2200 nm), a window/lens may be made of a silica lens coated with a film of MgF₂ (or made entirely of MgF₂) to restrict wavelength transmission to detector between 400 nm-700 nm. This restriction will eliminate near infrared (IR) wavelengths that can be the result of thermal radiation emission from surrounding components, and also prevent higher energy ultra-violet (UV) wavelengths from damaging the image detector. In additional embodiments, filters may be deposited directly on an image detector array, or incorporated in the image detector design and fabrication.

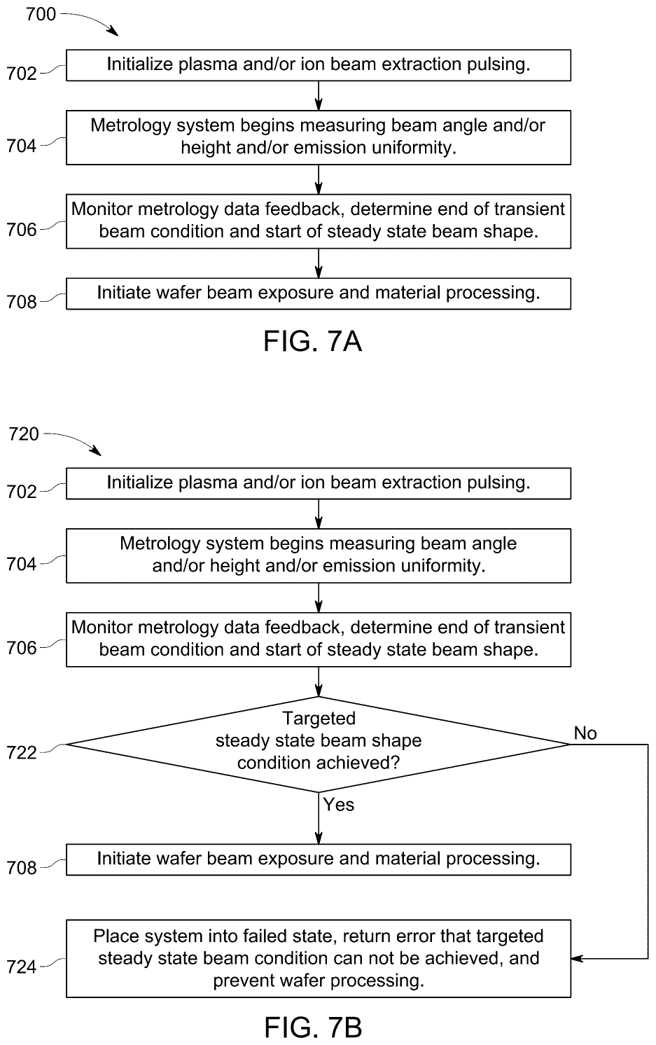

FIG. 7A depicts an exemplary process flow 700. At block 702 a plasma is initiated in a plasma chamber and an ion beam is extracted from the plasma chamber. The ion beam may be directed to a process chamber of a processing system, and in particular to a substrate position or substrate platen that is situated at a distance from a side of the plasma chamber. The plasma chamber may be part of a capacitively coupled plasma system, inductively coupled plasma system, a DC based plasma system, such as an indirectly heated cathode system, a pulse laser system, a glow discharge system, according to some non-limiting embodiments. The plasma system may employ an extraction bias plate, or gridded or plate extraction optics where a wafer/platen can be mounted, such that ions are extracted from an ion source and directed to a substrate with an energy proportional to the bias voltage between ion source and substrate. In some embodiments, a radical beam including energetic neutrals, radicals, and optionally ions may be extracted from a plasma chamber, and in one variant no bias need be applied between substrate and plasma chamber.

At block 704, a metrology system is employed to measure the ion beam in-situ while the ion beam is extracted from the plasma chamber and directed to the process chamber where substrates are to be processed. In various embodiments, the metrology system may employ a solid state detector, such as a two-dimensional pixel array to receive electromagnetic radiation emitted by species in the region of the ion beam, where the electromagnetic light is in the form of visible light, deep or near UV light, infrared light, or a combination of the above. The metrology system may include logic, electronic processors, routines operable on a processor, volatile and non-volatile memory, and/or other components to determine various properties of the ion beam based upon measurements of the ion beam received at the detector. In some non-limiting embodiments, such properties may include beam angle, beam height, emission uniformity, or a combination of the above.

At block 706, metrology data feedback is monitored. The monitoring may involve receiving a series of beam images that are recorded by the detector and identifying any changes in the images, such as changes that correspond to changes in beam properties. The end of a transient beam condition, where the beam features are fluctuating, and the start of a corresponding steady state beam shape condition with steady beam shape and performance may be determined in this manner.

At block 708, exposure of a set of substrates and materials processing is commenced after the steady state beam shape condition is established.

In some embodiments, if the steady state beam shape cannot be achieved, the system may enter a failed state, return an error indicating steady state beam condition could not be achieved, and prevent wafer processing. FIG. 7B depicts another exemplary process flow 720. In this example, the flow proceeds as in exemplary process flow 700 up through block 706. The flow then proceeds to block 722, where a determination is made as to whether a targeted steady state beam shape condition has been met. The targeted steady state beam state may be based on any suitable criterion. For example, the targeted steady state beam shape may refer to stability of the shape, size, and or angle of the ion beam within determined limits, or may refer to the ability to achieve a certain predetermined beam angle or beam shape.

At block 722, if the targeted steady state beam shape is not achieved, the flow proceeds to block 724, where various procedures may be performed, including placing the processing system into a failed state, returning an error indicating the targeted steady state beam condition cannot be achieved, and preventing wafer processing.

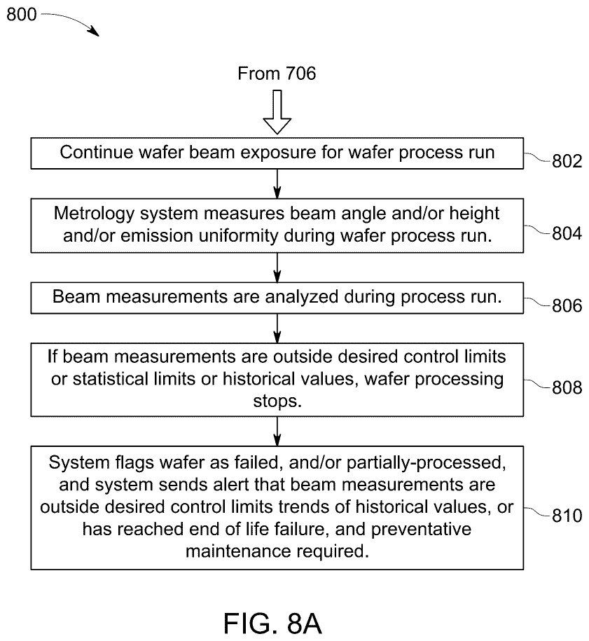

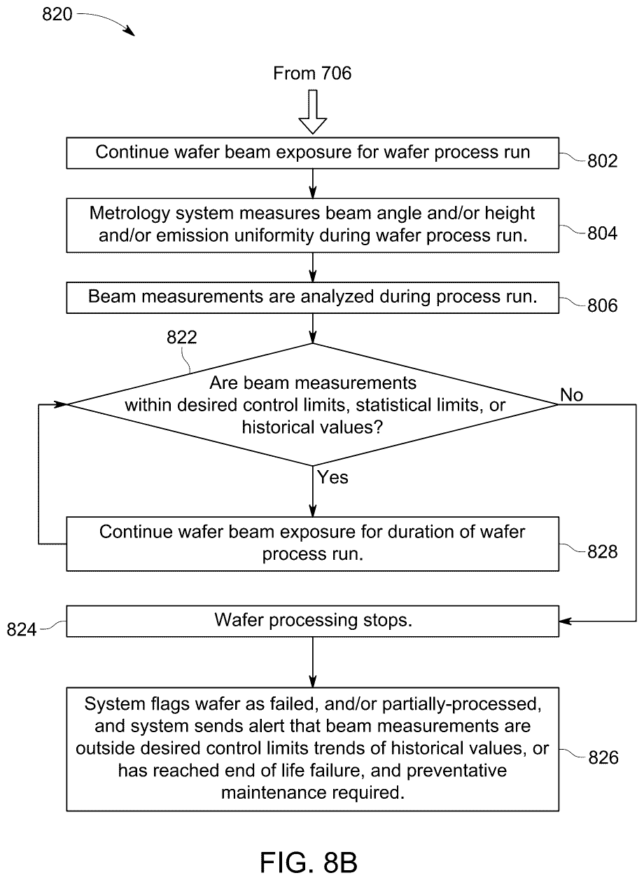

FIG. 8A depicts a process flow 800. The flow begins with blocks 702, 704, and 706, described previously. At block 802, wafer beam exposure is continued for a wafer process run. At block 804, the metrology system performs beam measurements including measuring beam angle and/or height and/or emission uniformity during the wafer process run.

At block 806, beam measurements are analyzed during the process run in real time.

At block 808, when beam measurements are determined to lie outside desired control limits or statistical limits or historical values, wafer processing stops.

At block 810, based upon the determination made at block 808, the system flags a wafer as partially-processed, and the system sends alert that beam measurements are outside desired control limits, trends of historical values, or has reached end of life failure, and preventative maintenance is required. In this manner, wafer processing can be continued and finished before process completion, with the potential to avoid scrapping a wafer due to misprocess.

In certain embodiments, these measurements and data comparisons may be repeated in a closed loop fashion, such that beam measurements are taken, and/or compared in a periodic fashion. The periodicity of such an embodiment may be based on the number of images between comparisons, or by a period of time between comparisons between the recently analyzed value and the control limits, statistical limits, or historical values. Some instances may repeat measurement and comparisons every time an image is taken (i.e. each frame in a video camera) to maximize the data collection and monitoring accuracy. Other instances may utilize an interval of every n frames or s seconds to reduce the processing power and memory required for data and image processing by electronic processor or computer 304.

FIG. 8B depicts another exemplary process flow 820. In this example, the flow proceeds as in process flow 800 up through block 806. At decision block 822, a determination is made as to whether beam measurements may lie within certain limits, such as within desired control limits, statistical limits, or historical values. If so, the flow proceeds to block 828 where a set wafer is exposed to an ion beam for a duration of a wafer process run. The flow then proceeds back to decision block 822. As noted, the instances where decision block 822 is performed, or the periodicity at which time the block 822 is performed may be set according to certain criteria. If, at decision block 822, the beam measurements to not lie within the certain limits, the flow proceeds to block 824, where wafer processing stops. The flow then proceeds to block 826, where the processing system performs a set of procedures, such as flagging the current wafer process as failed, and/or partially-processed, sending an alert indicating beam measurements are outside desired control limits trends of historical values, or indicating the optics have reached an end of life failure, indicating preventative maintenance is required.

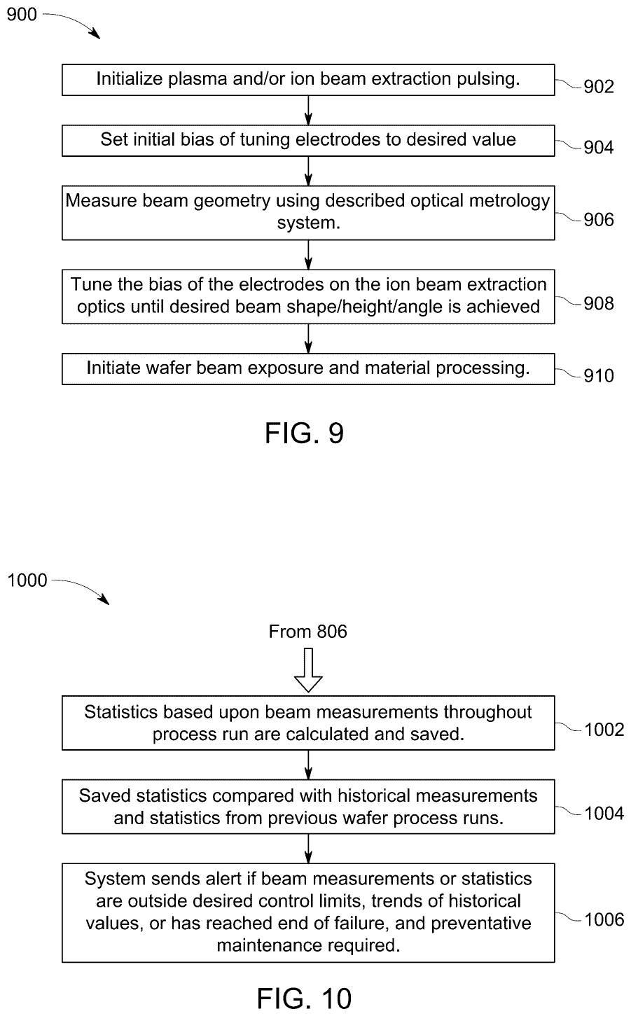

FIG. 9 depicts another exemplary process flow 900. At block 902, a plasma is initiated in a plasma chamber and an ion beam is extracted from the plasma chamber, as described with respect to block 702. In this embodiment, the processing system may include an electrode tuning system, such as described with respect to FIG. 2C.

At block 904 an initial bias of the tuning electrodes is set to a desired value. The desired value may be a value that is set to direct the extracted ion beam to achieve a targeted beam geometry, such as a targeted beam angle with respect to a substrate normal, at a targeted angular spread, a targeted beam height, a combination of the above, and so forth.

At block 906 an in-situ metrology system as detailed with respect to the above embodiments is used to measure the beam geometry of the extracted ion beam that is generated at the initial bias of the tuning electrodes.

At block 908, based upon the measurement of the in-situ metrology system, the bias of the tuning electrodes of the electrode tuning system are tuned until a targeted beam geometry, such as a desired beam shape/height/angle is achieved.

At block 910, exposure of a set of substrates and materials processing is commenced after the targeted beam geometry is achieved.

FIG. 10 depicts another exemplary process flow 1000. The flow begins with from block 806, described previously. At block 1002, statistics based upon beam measurements throughout the process run are calculated and saved.

At block 1004, saved statistics from the process run are compared with historical measurements and statistics from previous wafer process runs. At block 1006 after wafer processing in the process run is completed, the system sends an alert if beam measurements or statistics are outside desired control limits, trends of historical values, or has reached end of failure, and preventative maintenance required. This latter approach may help prevent additional wafer mis-processes, but may not save the most recently processed wafer.

In various embodiments, the aforementioned controller 130 may automate the operation of the embodiments as described above with respect to FIGS. 1A-10. In some embodiments, the controller 130 may be included in the computer 340, or as an adjunct to the computer 340. Returning to FIG. 1D, there are shown further details of the controller 130. In this embodiment, the controller 130 may include a processor 132, such as a known type of microprocessor, dedicated processor chip, general purpose processor chip, or similar device. The controller 130 may further include a memory or memory unit 134, coupled to the processor 132, where the memory unit 134 contains a beam shape control routine 136. The beam shape control routine 136 may be operative on the processor 132 to manage an ion beam processing operation using an ion beam 114, in order to monitor the ion beam 114, analyze the ion beam 114, ensure that the ion beam 114 satisfies certain criteria, terminate the ion beam processing operation, and send alerts or other messages when ion beam processing is not to continue as detailed herein above. In one embodiment, the memory unit 134 of controller 130 may be adapted to store various information, including control limits, statistical limits, or historical values, as discussed above.

The memory unit 134 may comprise an article of manufacture. In one embodiment, the memory unit 134 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In summary, advantages provided by the in-situ beam metrology approach of the present embodiments include at least the following. As one advantage, improved process repeatability is provided by in-situ monitoring of actual beam properties. The present approach can also ensure that beam angle, shape, and plasma distribution are at a steady state prior to processing each wafer. In this regard, note that initiating extraction pulse bias at the start of process may initiate a transient beam while the system stabilizes. Incorporating control systems to interact with the metrology can ensure steady state beam shape/angle condition is present before initiating wafer process. Another advantage is wherein the present approach provides monitoring of hardware performance of a processing system for individual runs and over time. Note that beam shape and beam angle of an ion beam will deviate if ion beam extraction optics fail or degrade over time. An in-situ metrology system based upon beam imaging may be used to determine when components require preventative maintenance, or are at end of life and require replacement. A further advantage is wherein the in-situ beam metrology approach may also characterize plasma process performance faster than ex-situ methods. Note that degradation and/or sub-par performance of ion beam extraction optics to guide an ion beam can lead to process results that deviate from the desired performance. Beam shape and angle will change if ion beam extraction optics fail, so that the present in-situ metrology approach enables the prevention of unacceptable wafer processing, as well as the automated determination of failed hardware, the need for preventative maintenance or replacement. Note that the effectiveness of reactive ion etch, layer deposition, and ion implantation via ion beam processing are heavily dependent on the incident angle of the plasma components (ion beam components). In-situ measurement according to the present embodiments may help maintain the incident angle, for example.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

What is claimed:

1. A processing system, comprising:
an ionizing chamber to ionize a gaseous species;
an extraction system, to extract a beam from the ionizing chamber and deliver the beam to a substrate, the substrate positioned external to the ionizing chamber; and
an in-situ beam metrology system, having at least one detector to image the beam in the processing system.

2. The processing system of claim 1, wherein the at least one detector comprises a two-dimensional array of pixels, arranged to intercept light generated by the beam.

3. The processing system of claim 2, wherein the two-dimensional array of pixels is arranged in an imaging plane, wherein the ionizing chamber is a plasma chamber, wherein the extraction system comprises an elongated extraction aperture that extends along an aperture axis that lies perpendicular to the imaging plane.

4. The processing system of claim 3, wherein the extraction system comprises a plurality of elongated extraction apertures extending along the aperture axis, the plurality of elongated extraction apertures arranged to generate a plurality of ion beams, wherein the at least one detector is arranged to intercept light from the plurality of ion beams.

5. The processing system of claim 2, wherein a two-dimensional image of the beam is recorded by the at least one detector.

6. The processing system of claim 5, further comprising an electronic processor to store and process the two-dimensional image.

7. The processing system of claim 2, further comprising a window and a filter, disposed between the beam and the two-dimensional array of pixels, the filter being arranged to filter certain wavelengths of light that are generated by the ion beam, the window being arranged to transmit other wavelengths of light that are generated by the beam.

8. The processing system of claim 1, further comprising:
a controller, coupled to the 2-dimensional imaging component, and comprising:
a processor;
a memory unit coupled to the processor, including a beam shape control routine, the beam shape control routine operative on the processor to:
receive a measurement of the beam from the in-situ metrology system; and
determine at least one beam characteristic of the beam according to the measurement.

9. The processing system of claim 8,
the beam shape control routine operative on the processor to:
determine a steady state beam shape is reached based upon the measurement of the beam; and
initiate a wafer process run, comprising processing a set of wafers using the beam, after the steady state beam shape is reached.

10. The processing system of claim 8, wherein the at least one beam characteristic includes one or more of: a beam angle, a beam height, and an emission uniformity during a wafer process run.

11. The processing system of claim 10, the beam shape control routine further operative on the processor to:
terminate a wafer process run when the measurement of ion beam lies outside desired control limits, statistical limits, or historical values.

12. The processing system of claim 10, wherein the at least one beam characteristic comprises at least one of: a beam shape, a beam height, and a beam angle, the beam shape control routine operative on the processor to: adjust a bias on a set or tuning electrodes that guide the ion beam until a desired beam characteristic is achieved, including at least one of: a desired beam shape, a desired beam height, and a desired beam angle.

13. The processing system of claim 1, the beam comprising an ion beam, or a gas cluster ion beam.

14. A method of substrate processing, comprising:
directing a beam from an ionizing chamber to a substrate; and
measuring a beam characteristic of the beam using a metrology system that includes a 2-dimensional imaging component.

15. The method of claim 14, further comprising
determining a steady state beam shape is reached based upon the measuring; and
initiating a wafer process run, comprising processing a set of wafers using the beam, after the steady state beam shape is reached.

16. The method of claim 14, further comprising
using the metrology system, performing a beam measurement by measuring at least one of: a beam angle, a beam height, and an emission uniformity during the wafer process run.

17. The method of claim 16, further comprising
terminating the wafer process run when the beam measurement lies outside desired control limits, statistical limits, or historical values.

18. The method of claim 14, wherein the beam characteristic comprises at least one of: a beam shape, a beam height, and a beam angle, the method further comprising:
adjusting a bias on a set or tuning electrodes that guide the ion beam until a desired beam characteristic is achieved, including at least one of: a desired beam shape, a desired beam height, and a desired beam angle.

19. An in-situ metrology system to measure a beam, comprising:
a detector, arranged to intercept radiation from the beam over an imaging region that is disposed between an ionizing chamber and a substrate position, wherein the detector comprises a two-dimensional detector to generate a two-dimensional image of the beam.

20. The in-situ metrology system of claim 8, wherein the beam is formed in a process chamber, the in-situ metrology system further comprising:
a window, adapted for mounting on the process chamber; and
a filter, disposed between the beam and the two-dimensional array of pixels, the filter being arranged to filter predetermined wavelengths of light that are generated by the beam.
